(19) United States
(12) Patent Application Publication
(10) Pub. No.: US 2017/0365554 A1
(43) Pub. Date: Dec. 21, 2017

(54) POLYMER BONDING WITH IMPROVED STEP COVERAGE

(71) Applicant: SKYWORKS SOLUTIONS, INC., Woburn, MA (US)

(72) Inventors: Bradley Paul Barber, Acton, MA (US); Kezia Cheng, Lowell, MA (US)

(21) Appl. No.: 15/620,064

(22) Filed: Jun. 12, 2017

Related U.S. Application Data
(60) Provisional application No. 62/352,854, filed on Jun. 21, 2016.

(51) Int. Cl. H01L 23/528; H05K 5/00; H05K 5/06; H05K 5/02; H05K 5/03

(52) U.S. Cl. CPC H01L 23/5283; H05K 5/065; H05K 5/0247; H05K 5/0095; H05K 5/0208; H01L 2224/05551; H05K 5/03

(57) ABSTRACT

A system and method for packaging an electronic device are provided. The packaged electronic device may include a structure material having one portion with a first lateral cross-section, and at least one other portion with a second lateral cross-section, where at least one of a dimension and a shape of the second lateral cross-section is different than in the first lateral cross-section.

### CROSS-REFERENCE TO RELATED APPLICATIONS

This application claims the benefit of priority under 35 U.S.C. § 119(e) to co-pending U.S. Provisional Application No. 62/352,854, filed on Jun. 21, 2016, which is incorporated herein by reference in its entirety for all purposes.

### BACKGROUND

Many types of electronic devices include three-dimensional (3D) topography either as part of their integrated structure, or as part of their packaging structure. With the increasing use of smaller-sized features in microelectronic fabrication, it has become increasingly difficult to conform to and “cover” the surfaces of 3D features that define the underlying surface topography. For instance, voids may form at or near corners or other sharp-angled 3D features of the surface. These voids present potential sources for delamination of material from the underlying substrate.

### SUMMARY

The present disclosure relates generally to the field of semiconductor wafer processing technology. In particular, aspects and embodiments of the present invention relate to a structure material that can be configured for use in manufacturing packaged electronic devices, such as semiconductor devices, MEMS devices, and microfluidic devices. According to one aspect of the present invention, a bonding structure for packaging an electronic device is provided.

According to one embodiment a bonding structure for packaging an electronic device comprises a receiving substrate having a first surface including at least one three-dimensional structure, and a layer of structure material disposed on the first surface and including a first portion and a second portion, the second portion at least partially covering the at least one three-dimensional structure, the first portion having a first lateral cross-section and the second portion having a second lateral cross-section in which at least one of a dimension and a shape of the layer of structure material is different than in the first lateral cross-section.

In one example the first and the second lateral cross-sections are vertically oriented. In another example the second lateral cross-section has at least one of a different width dimension and a different height dimension than the first lateral cross-section. In another example the second lateral cross-section has a different shape than the first lateral cross-section.

In one example the first and the second lateral cross-sections are horizontally oriented. In another example the second lateral cross-section has a different shape than the first lateral cross-section. In another example the first lateral cross-section has a rectilinear shape and the second lateral cross-section has a curvilinear shape. In another example the first lateral cross-section has a rectangular or square shape and the second lateral cross-section has at least one tapered edge. In another example the second lateral cross-section has a trapezoidal shape. In another example the second lateral cross-section includes a hollow region. In another example the hollow region is centrally positioned. In another example a perimeter of the hollow region has at least one curve. In another example a perimeter of the hollow region has at least one right angle.

In one example the second portion has a different material composition than the first portion. In another example the second portion extends substantially across at least one dimension of the at least three-dimensional structure. In another example the second portion is disposed adjacent to an edge of the at least one three-dimensional structure.

In one example the bonding structure further comprises at least one electronic device disposed on at least a portion of the first surface of the receiving substrate. The layer of structure material may be constructed and arranged to form at least a portion of a cavity that surrounds the at least one electronic device.

According to another embodiment a transferable structure comprises at least one layer of structure material having a first portion and a second portion, the first portion having a first lateral cross-section and the second portion having a second lateral cross-section in which at least one of a dimension and a shape of the layer of structure material is different than in the first lateral cross-section.

In one example the first and the second lateral cross-sections are vertically oriented. In another example the second lateral cross-section has a different dimension than the first lateral cross-section and the different dimension includes at least one of a width and a height of the second lateral cross-section. In another example the second lateral cross-section has a rectilinear shape. In another example the first and the second lateral cross-sections are horizontally oriented. In another example the second lateral cross-section has a shape with at least one tapered edge. In another example the second lateral cross-section has a curvilinear shape. In one example the curvilinear shape forms a hollow ring. In another example the curvilinear shape forms two circular shapes. In one example the second lateral cross-section has a different width dimension than the first lateral cross-section. In another example the second lateral cross-section has a smaller width dimension than a width dimension of the first lateral cross-section. In one example the second lateral cross-section has a larger width dimension than a width dimension of the first lateral cross-section. In another example the second lateral cross-section has a rectilinear shape that includes a hollow region. In another example a perimeter of the hollow region has a rectilinear shape. In another example a perimeter of the hollow region has at least one curve. In one example the shape of the second lateral cross-section includes at least one curve. In another example the second lateral cross-section includes a hollow region.

In one example the at least one layer of structure material is a polymer. In one example the polymer is photosensitive.

In one example the transferable structure is disposed in a packaged module. In one example the packaged module is an electronic device module. In another example the electronic device module is a radio frequency (RF) device module. In one example the electronic device module includes an acoustic wave filter. In another example the packaged module is disposed in a wireless communications device.

According to another embodiment a packaged electronic device comprises a substrate, at least one electronic device disposed on the substrate, at least one electrode disposed on the substrate and connected to the at least one electronic device, the at least one electrode extending above a surface of the substrate, a layer of structure material disposed on at least a portion of the substrate and at least a portion of the at least one electrode, the layer of structure material constructed and arranged to define at least a portion of a cavity that includes the at least one electronic device, at least one portion of the layer of structure material disposed on at least a portion of the at least one electrode and having a lateral cross-section with at least one dimension that is different than a corresponding dimension of a lateral cross-section of another portion of the layer of structure material that is disposed on at least a portion of the substrate.

According to another embodiment a packaged electronic device comprises a substrate, at least one electronic device disposed on the substrate, a layer of structure material constructed and arranged to define a cavity that includes the at least one electronic device, a first portion of the layer of structure material disposed on at least a portion of the surface of the substrate and having a first lateral cross-section, and a second portion of the layer of structure material disposed on at least a portion of the at least one electrode, the second portion having a second lateral cross-section with at least one dimension that is different than a corresponding dimension of the first lateral cross-section.

According to another embodiment a method of forming a bonding structure for a packaged electronic device comprises depositing a layer of structure material onto at least a portion of a surface of a first substrate, masking the layer of structure material to define a masked region and an unmasked region of the structure material, the unmasked region of the structure material defined by a first portion with a first cross-section and a second portion with a second cross-section, the first cross-section and the second cross-section oriented horizontally and at least one of a dimension and a shape of the second cross-section is different than a dimension and shape of the first cross-section, exposing the masked and unmasked regions of the structure material to a source of light to at least partially cure the unmasked region, and removing the masked region of the structure material.

In one example the surface of the first substrate is defined by at least one three-dimensional structure and masking comprises aligning the second portion of the unmasked region to be positioned over at least a portion of the three-dimensional structure.

In one example the method further comprises depositing a layer of temporary bonding material onto the surface of the first substrate prior to depositing the layer of structure material.

In one example the method further comprises bonding the unmasked region of the structure material to a surface of a second substrate.

In another example the surface of the second substrate is defined by at least one three-dimensional structure and bonding comprises positioning the second portion to be disposed over at least a portion of the three-dimensional structure.

In one example the method further comprises removing the first substrate from the second substrate by removing the layer of temporary bonding material.

In another example the unmasked region defines at least one cavity when the second substrate is bonded to the unmasked region.

In another example the second substrate comprises at least one electronic device disposed on a portion of the surface of the second substrate that is within the at least one cavity.

According to another embodiment a method of forming a bonding structure for a packaged electronic device comprises depositing a layer of structure material onto at least a portion of a surface of a first substrate, masking the layer of structure material to define a masked region and an unmasked region of the structure material, the masked region of the structure material defined by a first portion with a first cross-section and a second portion with a second cross-section, the first cross-section and the second cross-section oriented horizontally and at least one of a dimension and a shape of the second cross-section is different than a dimension and shape of the first cross-section, removing the unmasked region of the structure material, and exposing the masked region of the structure material to a source of light to at least partially cure the masked region.

Still other aspects, embodiments, and advantages of these example aspects and embodiments, are discussed in detail below. Moreover, it is to be understood that both the foregoing information and the following detailed description are merely illustrative examples of various aspects and embodiments, and are intended to provide an overview or framework for understanding the nature and character of the claimed aspects and embodiments. Embodiments disclosed herein may be combined with other embodiments, and references to “an embodiment,” “an example,” “some embodiments,” “some examples,” “an alternate embodiment,” “various embodiments,” “one embodiment,” “at least one embodiment,” “this and other embodiments,” “certain embodiments,” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1A is a cross-sectional side view of an example of a transferable structure material attached to a preparation substrate before being transferred to a receiving substrate having a surface with one example of a three-dimensional feature;

FIG. 1B is a cross-sectional side view of the transferable structure material of FIG. 1A after it has been transferred to the receiving substrate and illustrates two locations where the structure material has failed to adhere to the topography of the receiving substrate;

FIG. 1C is a cross-sectional side view of an example of a transferable structure material attached to a preparation substrate before being transferred to a receiving substrate having a surface with another example of a three-dimensional feature;

FIG. 1D is a cross-sectional side view of the transferable structure material of FIG. 1C after is has been transferred to the receiving substrate and illustrates two locations where the structure material has failed to adhere to the topography of the receiving substrate;

FIG. 2 illustrates a perspective view of one example of a structure material disposed over a three-dimensional structure in accordance with one or more aspects of the invention;

FIG. 3 illustrates two examples for orientation of a lateral cross-section in accordance with one or more aspects of the invention;

FIG. 4 illustrates several examples of lateral cross-sections of structure material in accordance with one or more aspects of the invention;

FIG. 5 illustrates a perspective view of two examples of structure material in accordance with one or more aspects of the invention;

FIG. 6A is a flow chart illustrating an embodiment of a method in accordance with one or more aspects of the invention;

FIG. 6B is a flow chart illustrating an embodiment of a method for implementing one of the steps of FIG. 6A;

FIG. 6C is a flow chart illustrating an embodiment of a method for implementing one or more of the steps of FIG. 6A;

FIG. 6D is a flow chart illustrating an embodiment of a method for implementing one or more of the steps of FIG. 6A;

FIGS. 7A and 7B illustrate an act in the method of FIG. 6B;

FIG. 7C illustrates an act in the method of FIG. 6B;

FIG. 7D illustrates an act in the method of FIG. 6B;

FIG. 8A and 8B illustrate an act in the method of FIG. 6A;

FIG. 9A illustrates an act in the method of FIG. 6C;

FIG. 9B illustrates an act in the method of FIG. 6C;

FIG. 9C illustrates one example of a masked structure material according to one example of the method of FIG. 6C;

FIG. 9D illustrates another example of a masked structure material according to another example of the method of FIG. 6C;

FIG. 9E illustrates a perspective view of the structure material featured in FIGS. 9D and 9E;

FIGS. 10A and 10B illustrate an act in the method of FIG. 6D;

FIG. 10C illustrates an act in the method of FIG. 6D;

FIG. 10D illustrates an act in the method of FIG. 6D;

FIG. 10E illustrates an act in the method of FIG. 6D;

FIG. 10F illustrates an act in the method of FIG. 6D;

FIG. 10G illustrates an act in the method of FIG. 6D;

FIG. 10H illustrates an act in the method of FIG. 6A;

FIG. 10I illustrates an act in the method of FIG. 6A;

FIG. 11 is a flow chart illustrating an embodiment of a method in accordance with one or more aspects of the invention;

FIG. 12A illustrates a cross-sectional side view of one example of an act performed according to the method of FIG. 11;

FIG. 12B illustrates a partial perspective view of one example of the structure material formed by one or more acts of FIG. 11;

FIG. 13 is a block diagram of one example of a device that can be fabricated according to aspects of the present invention;

FIG. 14 is a block diagram one example of a module having one or more features according to aspects of the invention; and

FIG. 15 is a block diagram of one example of a wireless device having one or more features according to aspects of the invention.

### DETAILED DESCRIPTION

Aspects and embodiments are directed to a method of forming a packaged electronic device using a structure material that is configured to conform to three-dimensional features, such as steps and recesses that define the surface topography of an underlying substrate. As used herein, the term “structure material” may be used to refer to one or more materials which are used to form features that may be implemented into electronic devices or into packaged electronic devices. For instance, according to some embodiments, the structure material may be used to package one or more electronic devices. The structure material used in these types of applications may bond to a receiving substrate and form at least a portion of a perimeter or enclosure around the electronic device that functions to encapsulate and seal the device from the external environment. As used herein the term “bonding structure” refers to all or a portion of the packaging that functions to protect the electronic devices, and in certain instances may also provide electrical connections with the higher level circuit structures into which the electronic devices are incorporated.

According to certain embodiments, the structure material may be constructed and arranged to include one portion having a first lateral cross-section and at least one other portion having a second lateral cross-section with a different configuration than the first lateral cross-section. For example, according to some embodiments, the second lateral cross-section has at least one different dimension than the first lateral cross-section. In one or more embodiments, the second lateral cross-section has a different shape than the first lateral cross-section. According to some embodiments, at least one portion of the structure material may be constructed from a material having a different material composition than other portions of the structure material. The portions of the structure material having the different configuration are designed to conform to 3D structures defining the surface of the underlying substrate.

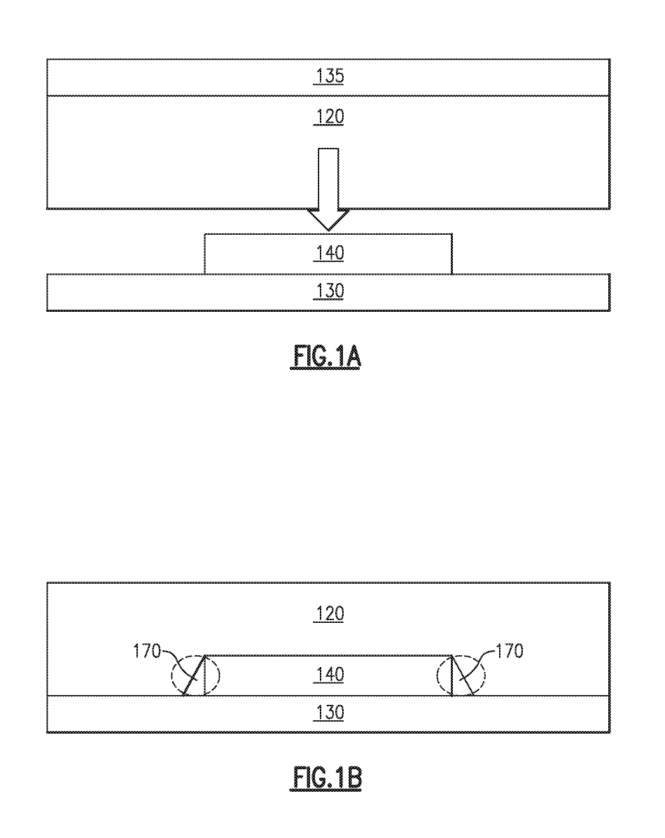

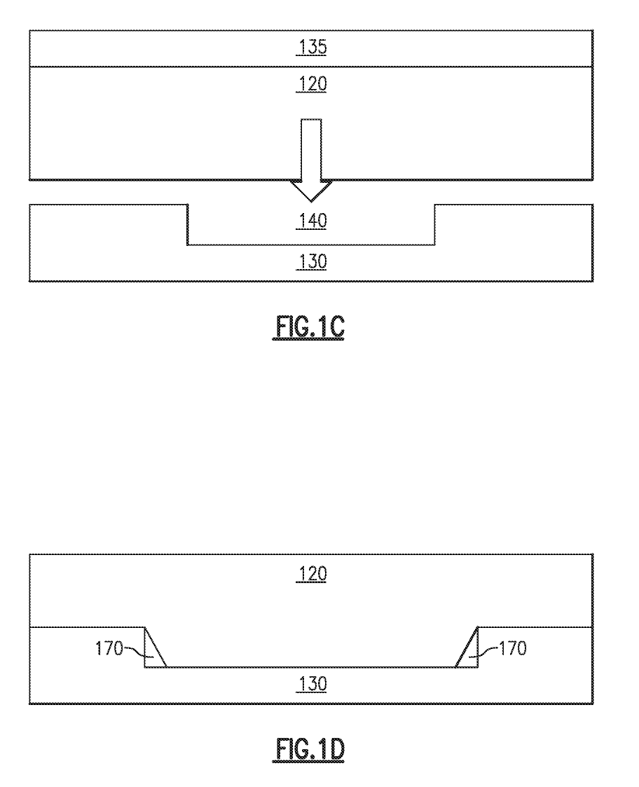

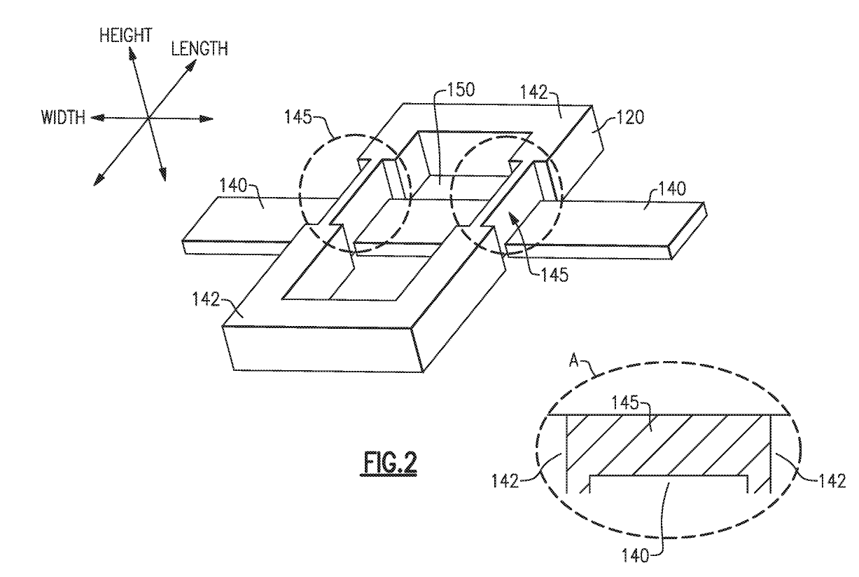

As discussed above, one or more layers of structure material may be integrated into electronic devices and/or their packaging. The structure material may be disposed onto a surface that includes 3D structures and therefore may be required to conform to the 3D structures, such as steps and recesses. According to various aspects, the structure material is configured to create microstructures that may be used in one or more applications, such as electronic device packaging, electronic devices, for example, MEMS devices, and microfluidics. In certain instances, the structure material may be prepared or created on a separate preparation substrate and then transferred and bonded to a receiving substrate, such as a device substrate, to fulfill a desired functionality. FIG. 1A in combination with FIG. 1B, and FIG. 1C in combination with FIG. 1D illustrate two examples of such a process.

FIGS. 1A and 1C illustrates a layer of structure material 120 that is attached to a preparation substrate 135 before it is transferred to a receiving substrate 130 that includes a 3D feature 140 (also referred to herein as a 3D structure) in its surface topography. The 3D feature 140 may be any kind of feature that creates a non-planar or non-uniform topography to the surface of the receiving substrate 130, such as recesses (e.g., as shown in FIGS. 1C and 1D) and raised features such as steps or other types of projections (e.g., as shown in FIGS. 1A and 1B). According to some embodiments, the 3D feature 140 may comprise metallization lines, electrodes, or other raised conductive electronic device features. As indicated by the arrows in FIGS. 1A and 1C, the structure material 120 may be lowered and bonded to the surface of the receiving substrate 130. The preparation substrate 135 may then be released and removed, leaving behind the receiving substrate 130 and its feature 140 covered by the structure material 120, as shown in FIGS. 1B and 1D.

The material properties of the structure material 120 allow it to conform and cover planar surfaces of the underlying receiving substrate; however, as illustrated in FIGS. 1B and 1D, one or more voids 170 may form in certain regions of the surface of the receiving substrate 130 in the vicinity of the 3D feature 140. For instance, voids 170 may form at the bottom corners and edges of the “step” or “recess” forming the 3D feature 140 where it meets the receiving substrate 130 as shown in FIGS. 1B and 1D, respectively. The voids 170 are caused because the structure material 120 is not “pliable” or “flexible” enough to completely conform to the contours of the 3D feature 140. As discussed in further detail below, according to certain aspects, this problem can be addressed by providing a localized region of the structure material that is shaped and/or sized and/or has different material properties to more readily conform to the 3D features 140.

For instance, a portion of the structure material 120 positioned at or near the 3D feature 140 may be configured to have a different dimension, such as a different width, and/or a different shape, and in some instances, may have a different material composition than other portions of the structure material 120. These localized changes allow for the structure material 120 to be more “flexible” and conform to all or at least a portion of the edges and contours of the 3D features forming the topography of the surface of the receiving substrate 130. This prevents the formation of the voids 170 illustrated in FIGS. 1B and 1D.

Previous attempts to address this problem have included a number of different approaches. One such approach includes using greater force when bonding the structure material 120 to the receiving substrate 130, but this can cause other problems, such as deformations in the structure material, damage to other components of the device and/or packaging, and in some instances, once the force is released, the structure material “springs” back or otherwise retracts away from the contours of the 3D feature and voids are formed. Another such example includes using a very “flexible” structure material, but these materials may not hold their shape and/or do not provide enough strength, which can lead to device failure (e.g., loss of a hermetic seal, damage to other components, etc.). Another approach has been to perform extra processing steps to eliminate the 3D features from the substrate surface, such as by performing a planarization procedure. However, this increases both processing time and costs.

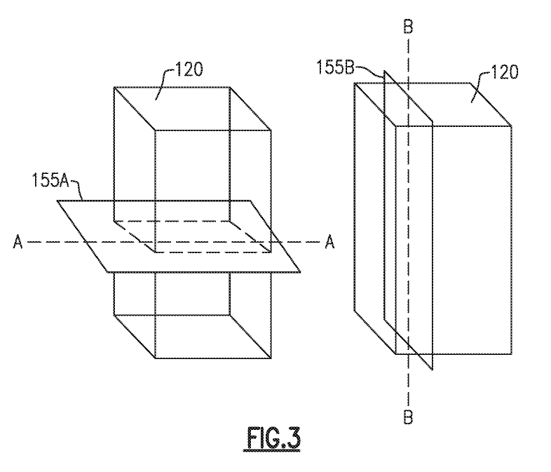

In accordance with one embodiment, FIG. 2 illustrates an example of a structure material 120 that is disposed over a 3D feature 140. In this instance, the 3D feature 140 is a step, and although not explicitly shown in FIG. 2, a substrate may also be disposed underneath the 3D feature 140 and the structure material 120. As shown, the structure material 120 may form one or more “walls” that define a cavity 150. According to some embodiments, the cavity 150 may also include one or more electronic devices, and the walls may be used as a part of the bonding structure that seals and protects the electronic devices.

As shown in FIG. 2, the structure material 120 includes a first portion 142 having a first lateral cross-section with a set of dimensions, including a height, a length, and a width. For purposes of illustration, the upper left portion of FIG. 2 includes labels for the height, width, and length, but it is to be understood that the scope of this disclosure is not limited to these particular orientation labels, and other orientations are also possible. The term “lateral cross-section” of the structure material 120 disclosed herein refers to the cross-section taken along either the horizontal axis of the structure material 120 or the vertical axis of the structure material 120, as shown for purposes of illustration in FIG. 3. For instance, the left side of FIG. 3 shows a horizontally-oriented lateral cross-section of structure material 120, indicated at line A-A and 155A, and the right side of FIG. 3 shows a vertically-oriented lateral cross-section of structure material 120, indicated at line B-B and 155B. In the discussion herein, and in the example embodiment shown in FIG. 2, the lateral cross-section that is oriented horizontally corresponds to the width of the structure material 120, and the lateral cross-section that is oriented vertically corresponds to the height of the structure material 120.

Referring again to FIG. 2, the structure material 120 also includes a second portion 145, corresponding to the two circled regions, the second portion 145 having a lateral cross-section with one or more dimensions that are different than the lateral cross-section of the first portion 142. For instance, according to the embodiment shown in FIG. 2, the horizontally-oriented lateral cross-section of the second portion 145 has a smaller width dimension than the corresponding width dimension of the lateral cross-section of the first portion 142. In the example shown in FIG. 2, the smaller width dimension of the lateral cross-section of the second portion 145 of the structure material 120 allows for this portion to “flex” or otherwise yield and conform to the contours of the 3D feature 140 of the underlying substrate. This allows the structure material 120 to conform to the edges of these 3D features, and avoid creating voids, such as the voids 170 of FIG. 1B. A side view (labeled “A”) of the second portion 145 is also shown in FIG. 2, where it has “flexed” to “wrap” around the step 3D feature 140. Although the 3D feature 140 is shown in FIG. 2 as a step, the configuration of the second portion 145 may also be used with a recessed 3D feature 140.

According to some embodiments, the second portion 145 of the structure material 120 is positioned or otherwise located to correspond to the 3D feature 140. In some embodiments, the second portion 145 may be disposed on at least a portion of a 3D feature 140. According to at least one embodiment, the second portion 145 may be configured to extend substantially along one or more dimensions of the 3D feature 140. For instance, the second portion 145 shown in FIG. 2 is configured to extend along the length of the step feature (140), and even extends slightly beyond the length of the step, as shown in side view “A.” As discussed in further detail below, according to some embodiments, the second portion 145 may be configured to be positioned or otherwise correspond to only certain regions of the 3D features, such as at the corners or edges.

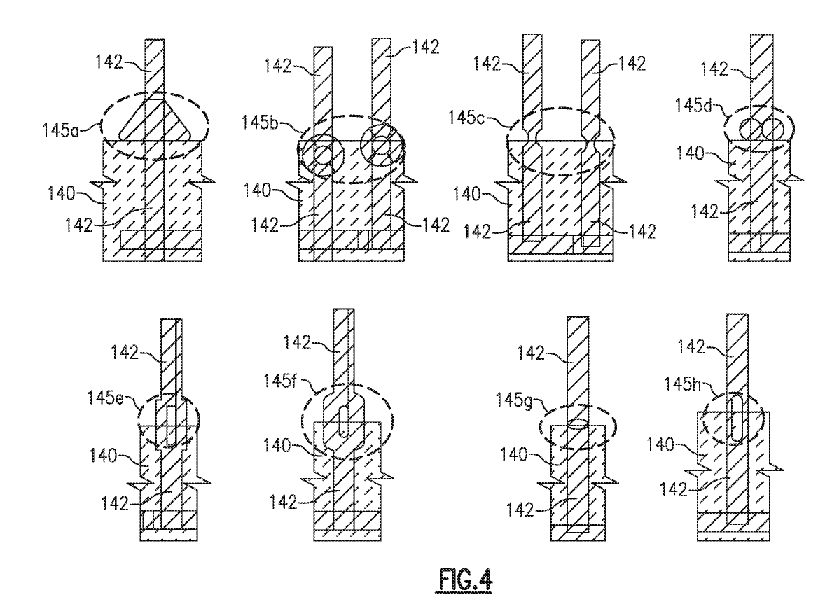

According to some embodiments, the second portion 145 may have a lateral cross-section with a different shape than the first portion 140. For instance, the first portion 142 may have a lateral cross-section with a rectilinear shape and the second portion 145 may have a lateral cross-section with a curvilinear shape or some other shape that differs from the rectilinear shape of the first portion 142. FIG. 4 includes several non-limiting examples of lateral cross-sections that may be constructed and used in the second portion 145 (see circled regions). For instance, the lateral cross-section for the second portion 145a includes at least one tapered edge and has a trapezoid shape. In contrast, the lateral cross-section of the first portion 142 is rectilinear in shape, which is the case for all the examples shown in FIG. 4. In addition, for purposes of discussion, the same geometric references as discussed above in reference to FIG. 2 are used, such that the lateral cross-section of second portions 145a-145h are all horizontally oriented. The lateral cross-section of the second portion 145a is positioned adjacent to one edge of the 3D feature 140, which in the examples shown in FIG. 4 is a step feature. As will be appreciated by those skilled in the art given the benefit of this disclosure, the second portion 145a may also be positioned adjacent to the other edge of the 3D feature 140 in a mirror-like configuration. The second portion 145, including any of the examples shown in FIG. 4, may be positioned at multiple locations in the vicinity of the 3D feature 140, including at one or both edges of a step or recess.

The lateral cross-section of the second portion 145b has a curvilinear shape and includes at least one void that is centrally positioned such that it forms a hollow ring. In this instance, the second portion 145b is illustrated to show two different locations for placement on the 3D feature 140. For instance, an edge of the second portion 145b shown on the left is positioned adjacent to the edge of the 3D feature 140, and the second portion 145b shown on the right is more centrally positioned over the edge of the 3D feature 140. In some embodiments the second portion 145 may be centered over the edge of the 3D feature 140.

Second portion 145c has a lateral cross-section that is similar to the cross-section shown in FIG. 2. In this instance, the outer edges of the second portion 145c are slightly rounded and therefore include at least one curve, instead of the straight-edged “I” shape shown in second portion 145 of FIG. 2. The second portion 145c shown on the left has one end positioned adjacent to the edge of the 3D feature 140, and the second portion 145c shown on the right has the other end positioned adjacent to the edge of the 3D feature 140. Other embodiments may include having the second portion 145 centered over the edge of the 3D feature 140.

Still referring to FIG. 4, the lateral cross-section of second portion 145d has a curvilinear shape that includes two circular shapes positioned adjacent to one another. Second portion 145d is also positioned to be adjacent to the edge of the 3D features 140. As will be appreciated, any of the second portion 145 configurations discussed herein may be positioned at one or more locations in the vicinity of the 3D feature(s), whether it be adjacent to an edge, centered over the edge, or extending partially or entirely over the 3D feature. The positioning may depend on the application, the types of materials used, and the geometry and size of the 3D feature 140.

In accordance with some embodiments, the second portion 145 may include a void or hollow region. For example, second portion 145e of FIG. 4 has a lateral cross-section with a rectilinear shape that includes a hollow region. In this instance, the perimeter or periphery of the hollow region also has a rectilinear shape, but in other instances the perimeter of the hollow region may take on the form of other shapes, such as an irregular shape, or may include at least one curve (e.g., second portions 145f and 145g). For instance, second portions 145f and 145g each have a lateral cross-section with a curvilinear shape that also includes a hollow region, In this example, the perimeter of the hollow region has at least one curve, although other shapes for the perimeter of the hollow region are within the scope of this disclosure. The hollow regions or voids formed in the second portion 145 may be of any shape or size and in some instances may only extend partially through a depth or thickness of the second portion 145. In the example shown by second portions 145f and 145g, the hollow region is elliptical in shape, and as with second portion 145e, is illustrated to be centrally positioned over one edge of the 3D feature 140.

Viewed from the top, the major axis, i.e., longer diameter of the hollow region of second portion 145f is oriented to be perpendicular to the edge of 3D feature 140, whereas the major axis of the hollow region of second portion 145g is oriented to be parallel to the edge of 3D feature 140. However, the second portion 145 may be positioned adjacent to or anywhere else in the vicinity of the 3D feature where it may aid or otherwise allow the structure material to conform to the contours of the 3D feature and the substrate.

According to some embodiments, the second portion 145 may have a different material composition than the first portion 142. For example, in accordance with one or more embodiments, the second portion 145 may have a material composition with one or more rheological properties that differ from those of the first portion 142, such that the second portion 145 is more elastic, flexible, and/or conformable. Having these different material properties may render the second portion 145 with physical properties that allow it to more easily conform to the edges and recesses of the underlying 3D topography, and therefore avoid gaps or voids. For instance, the first portion 142 may be formed from a first type of polymer material, and the second portion 145 may be formed from a second type of polymer material, where the second type of polymer material has different physical properties than the first type of polymer material that render it capable of conforming to 3D components of the underlying substrate. According to another embodiment, first portion 142 and second portion 145 may be made from the same material, or from different materials, but cured under different conditions. For instance, first portion 142 may be more “fully” cured than second portion 145, and may therefore undergo a longer curing time and/or higher curing temperature than second portion 145. In some instances, second portion 145 may be B-stage cured to render it more “conformable” as opposed to first portion 142, which may undergo a more “complete” cure or “full” cure. For example, a first mask may be used to define a polymer forming the first portion 142, which may then be cured, and after unexposed portions of the polymer have been removed, a second layer of the same or a different polymer may be deposited. A second mask may then be used to define the second layer of the same or different polymer forming the second portion 145. A lesser-stage cure, such as a B-stage cure, may then be performed on the second portion 145.

According to some embodiments, second portion 145 may have a lateral cross-section with the same dimensions and shape as the first portion 142, but have a different material composition than the first portion 142. In other examples, the second portion 145 may not only have a different material composition, but may also be configured to have a lateral cross-section with a different dimension and/or size relative to the first portion 142. Second portion 145h of FIG. 4 illustrates an example where the second portion 145h has a different material composition than the first portion 142 and is disposed within the first portion 142 such that it is completely surrounded by the first portion 142. In the illustrated example, the second portion 145h has a lateral cross-section with a curvilinear shape, which in this instance is elliptical, that is centered within the “width” of the first portion 142. However, a second portion 145 with a different material composition may have different dimensions and/or may take on any one of a number of different shapes, including curvilinear, rectilinear, and irregular shapes, and may be positioned at one or more locations in the structure material 120 in relationship to the first portion 142. For instance, the second portion may be placed “within” the outer boundaries of the width dimension of the first portion 142, as shown by second portion 145h, or may extend partially beyond the outer boundaries of one or more dimensions of the first portion 142, or may be distinct from the first portion 142 (such as in second portions 145a-145g). The second portion 145 having the different material composition may take on any shape or dimension, which may depend on the geometries and materials of a particular application.

The geometric configurations for the lateral cross-sections illustrated in FIG. 4 are non-limiting, and as will be appreciated, other shapes and configurations are also within the scope of this disclosure. One or more of the examples 145a-145h illustrated in FIG. 4 feature thin walls that contribute to a high success rate when transferring the structure to a device substrate and covering the 3D features disposed on the device substrate. Thicker walls result in a stronger bond, i.e., stronger seal, onto planar surfaces of the device substrate when the bonding step occurs. According to certain embodiments, the lateral cross-section is configured to balance these attributes. As an illustrative example, lateral cross section 145a includes a trapezoid shape that is wider and therefore provides a stronger bond to the device substrate, whereas thinner portions are better configured to “conform” to the step feature included on the device substrate.

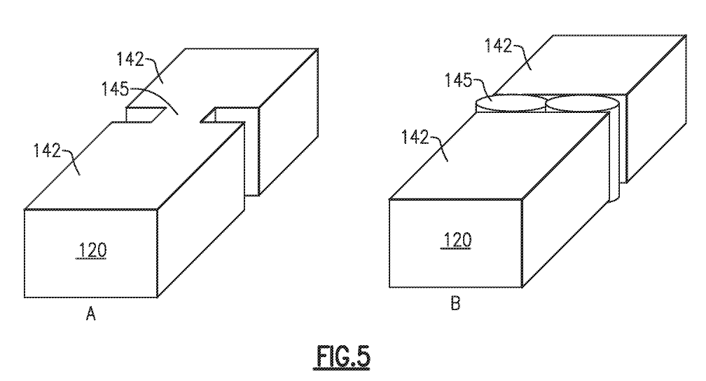

FIG. 5 illustrates perspective views of two examples, labeled “A” and “B” of a structure material 120 that includes a first portion 142 and a second portion 145 as discussed above. The structure material 120 labeled “A” is similar to a portion of the structure material 120 illustrated in FIG. 2, and includes a first portion 142 and a second portion 145 having a lateral cross-section with a smaller width dimension than the corresponding lateral cross-section of the first portion 142. The structure material 120 labeled “B” includes a first portion 142 and a second portion 145 that is similar to second portion 145d shown in FIG. 4, and the second portion 145 has a lateral cross-section with a different shape than the corresponding lateral cross-section of the first portion 142, which in this instance is rectilinear in shape.

As will be appreciated, the scope of the disclosure is not limited to the shapes and dimensions of the examples shown in FIG. 4, and other shapes and dimensions for the lateral cross-section of the second portion 145 are within the scope of this disclosure. For instance, other rectilinear, curvilinear and even irregular shapes, or combinations of these shapes are also within the scope of this disclosure. Further, although the shapes of second portions 145a-145h of FIG. 4 are shown to be of a lateral cross-section that is oriented horizontally, the orientation may also be or instead be oriented vertically. All of the variations related to the dimensions, size, shape, and/or composition of the second portion 145 are configured to render the structure material 120 more capable of conforming to the contours of the 3D features 140 forming the surface of the receiving substrate 130. For instance, using a material with thinner dimensions, as shown in FIG. 2, may allow the second portion 145 to bend or flex more readily than the thicker dimensions of the first portion 142. The configuration of the second portion 145 allows the structure material 120 to conform to the corner and angled surfaces of the receiving substrate 130 and avoids the formation of voids such as the voids 170 shown in FIGS. 1B and 1D.

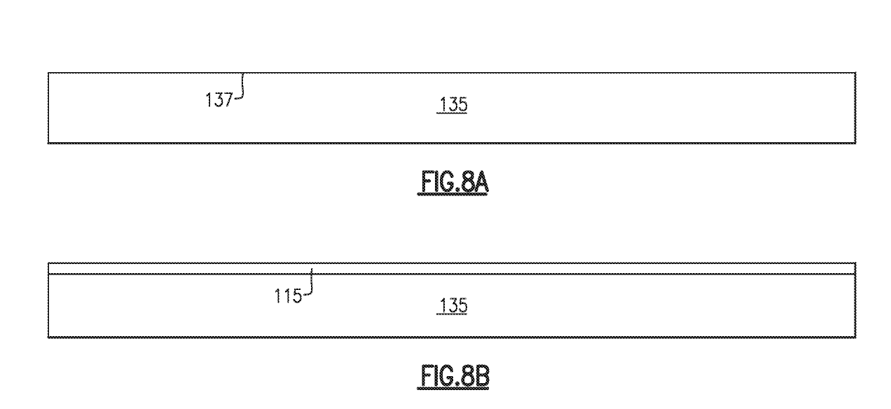

In accordance with at least one embodiment, the structure material 120 may be formed on a separate preparation substrate 135 and then transferred to a device or other receiving substrate 130. One such example of a transferable structure material is discussed in commonly-owned U.S. patent application Ser. No. 15/440,223, filed Feb. 23, 2017, titled 3D MICROMOLD AND PATTERN TRANSFER, which is incorporated herein by reference in its entirety (herein referenced as “the '223 application”). The '223 application uses a recyclable template substrate (also referred to herein as a “preparation substrate”) with a surface having a 3D topography to create transferable structures that may be attached to a receiving substrate, and in certain instances, may complement or attach to three-dimensional features present on the receiving substrate. However, according to some embodiments, the preparation substrate need have a 3D topography, and instead may have a planar surface, as shown in FIGS. 8A and 8B. The ability to create structures with a 3D topography on a separate substrate allows for complex, multi-level structures with features of varying sizes and shapes to be transferred to a receiving substrate, such as a device substrate that includes one or more electronic devices. Thus, transferable structures with varying features that are constructed from structure material may be created externally for use as one or more components of the electronic device and packaging. For example, once bonded or otherwise attached to the receiving substrate, the transferable structure material may form a cavity that can be used to hermetically seal or otherwise encapsulate one or more electronic devices housed within the cavity. Non-limiting examples of electronic devices include semiconductor die, MEMS devices, and other electrical components that may be used according to one or more embodiments of the present invention. In certain instances, the electronic device may include or be part of a larger system, as discussed further below. Non-limiting examples of electronic devices include MEMS or acoustic wave devices, such as surface acoustic wave (SAW) filters or bulk acoustic wave (BAW) filters, or other similar acoustic wave components. For example, interdigitated transducer (IDT) electrodes of a SAW filter may be disposed on the receiving substrate within the cavity. Similar processing and manufacturing techniques may be used according to at least one embodiment of the methods and systems disclosed herein.

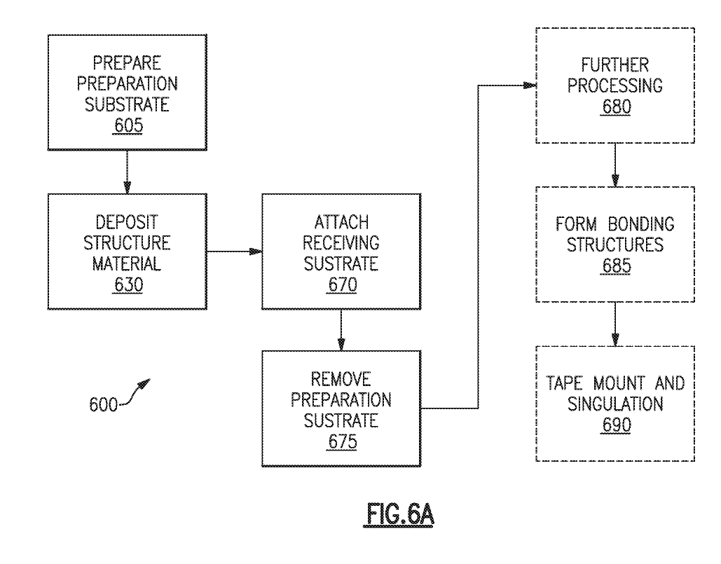

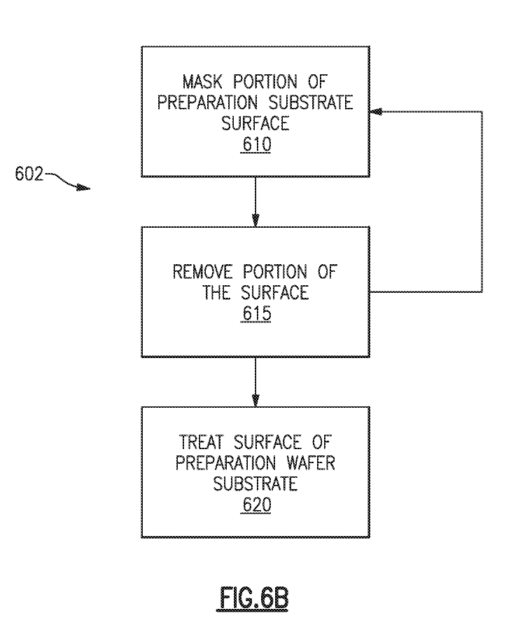

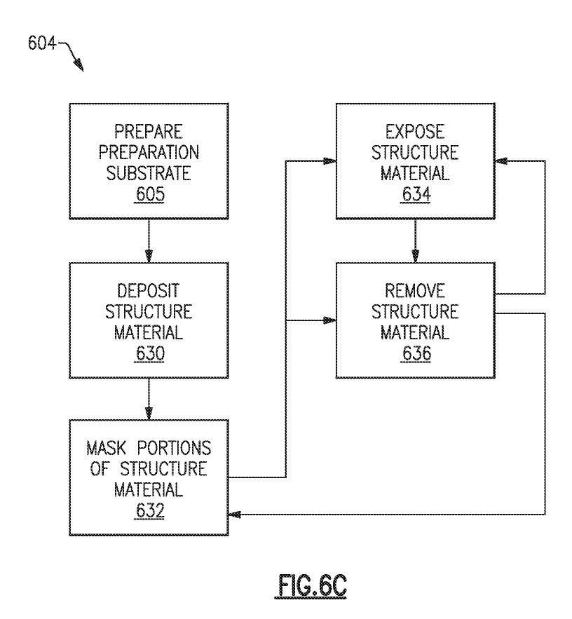

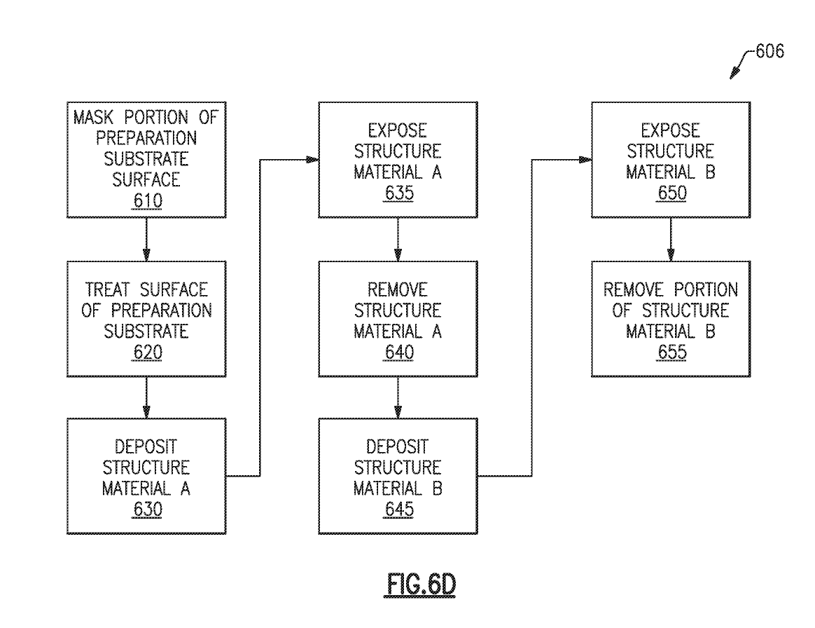

According to certain embodiments, FIG. 6A illustrates a flow diagram of one example of a method 600 of forming a packaged electronic device, and includes one or more of the elements discussed above in reference to FIGS. 2, 4, and 5. Although the discussion below references a single package, it is to be understood that the method may be applied to forming multiple packages on a common substrate or wafer. For example, step 690 includes singulation, where the receiving substrate may be diced to individually separate the packaged electronic devices from one another.

A first step 605 includes preparing a preparation substrate 135. According to some embodiments, the preparation substrate 135 may be constructed from a material that is transparent to UV light. Non-limiting examples of UV transparent materials include silicon carbide (SiC), sapphire, silicon, silicon nitride (SiN), quartz, and gallium arsenide (GaAs). According to some embodiments, the preparation substrate 135 may be constructed from silicon.

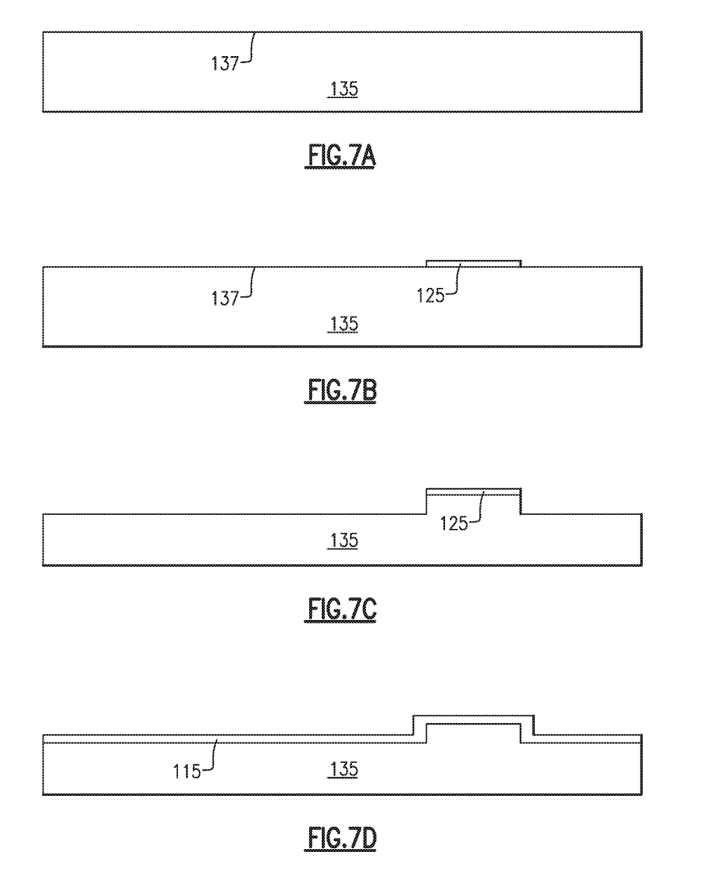

FIG. 6B illustrates one embodiment of a process 602 for preparing the preparation substrate 135. The process starts at step 610 by taking a preparation substrate 135 (see FIG. 7A) and masking at least a portion of its upper or first surface 137 (see FIG. 7B). Masking may be performed using any one of a number of different techniques, such as by using a photolithographic method, or by using a shadow or stencil mask. For example, a masking material 125 may be deposited or positioned onto the upper surface 137 of the preparation substrate, as shown in FIG. 7B. According to this example, the masking material 125 functions to protect the masked region of the preparation substrate 135 when the unmasked region is exposed to a removal process at step 615, such as an etch process or other form of removal, which etches away or otherwise removes the unmasked portions of the upper surface 137, as shown in FIG. 7C.

According to some embodiments, the masking material 125 is configured to create the first portion 142 and/or second portion 145 of the structure material, including the lateral cross-sections of the second portion 145 discussed above. The masking material 125 may be removed in a separate step (not shown).

As an alternative option to the masking technique discussed above, a photolithographic method may be used to create the topography of the preparation substrate 135. For example, a photolithographic method may comprise depositing a layer of photolithographic resist material, also referred to herein as simply “photoresist,” on the entire surface of the preparation substrate 135 using a spin-coat technique, which is followed by positioning a photomask over the layer of photoresist material, as will be recognized by those of skill in the art. Light may be applied through the photomask to the underlying photoresist material, thereby causing a chemical reaction to portions of the photoresist material that correspond to a desired pattern defined by the photomask. In certain instances, the light polymerizes the photoresist material, thereby hardening it and making it resistive to certain solvents and allowing it to protect the surface of the preparation substrate 135 underneath. As with the masking technique discussed above, a portion of the surface of the preparation substrate 135 is removed at step 615. For instance, the surface of the preparation substrate 135 may be etched using a wet etch process by exposing the surface to one or more solvents, which may etch away the unreacted photoresist material (if not removed in a separate step) and at least some of the underlying material that forms the preparation substrate 135. In other examples, a dry etch process may be used to remove a portion of the surface of the preparation substrate 135, as understood by those of skill in the art.

The photolithographic processes discussed herein with reference to forming structure material 120 refer to a type of photosensitive material that polymerizes or otherwise reacts with light to form a hardened layer. As will be appreciated by those of skill in the art, other types of photosensitive material may be used, such as those that actually photo-solubilize when exposed to light. Thus, exposed portions of this type of material are removed, and the unexposed portions actually form the portions of the structure material 120 that are then transferred to the device wafer. Additional steps may be performed to render this type of structure material suitable for transfer.

The resulting surface topography of the preparation substrate 135 after undergoing the masking 610 and removal 615 processes includes three-dimensional structures, thereby creating a surface with a 3D topography that may include the first portion 142 and second portion 145 of the structure material 120. As indicated by the arrow in FIG. 6B going from step 615 to step 610, the mask and removal process may be repeated, with the next repetition using a mask with a different pattern that results in the removal of different portions of the preparation substrate. Rounded, stepped, and features with “slanted,” nonlinear, and/or continuously varying surfaces may all be created using these masking and removal steps.

At step 620, the preparation substrate 135 created in steps 610 and 615 may be treated so that the first surface 137 has or is otherwise characterized by a low bond strength. A low bond strength allows for relative ease in the removal of the preparation substrate 135 from the structure material 120 once the structure material 120 has been transferred to the receiving substrate 130. For example, according to one embodiment, a layer of temporary bonding material 115 may be deposited on the first surface 137 of the preparation substrate 135, as shown in FIG. 7D. Non-limiting examples of temporary bonding material include polyvinyl alcohol (PVA), Omnicoat™ (commercially available from MicroChem Corp.), polymethylglutarimide (PMGI), and other low surface energy organic materials. According to some embodiments, the temporary bonding material 115 may be a halocarbon, such as tetrafluoromethane (CF₄) or sulfur hexafluoride (SF₆). According to some embodiments, the temporary bonding material 115 may be a material that is capable of being dissolved by selected solvents. The temporary bonding material 115 may be deposited using a spin-coat, and the temporary bonding material 115 may be deposited to a thickness that is in a range of about 2000 Angstroms to several microns.

FIGS. 8A and 8B illustrate an alternative embodiment for preparing the preparation substrate 135 of step 605. Instead of masking and removing a portion of the surface 137 of the preparation substrate prior to treating the surface 137 (i.e., steps 610-620), according to this embodiment, the preparation process includes taking a preparation substrate 135 (see FIG. 8A) and treating the first surface 137 so that it is characterized by a low bond strength (i.e., step 620). For example, according to one embodiment, a layer of temporary bonding material 115, as described above, may be deposited on the first surface 137 of the preparation substrate 135, as shown in FIG. 8B. This embodiment may be used in applications that utilize a preparation substrate 135 with a planar upper surface 137.

Referring again to method 600 of FIG. 6A, at step 630, one or more layers of structure material 120 are deposited onto at least a portion of the preparation substrate 135. According to certain aspects, the layer of structure material 120 may be deposited using spin coat or spray-on techniques. In accordance with at least one embodiment, the structure material 120 may include one or more polymer materials. In some embodiments, the polymer material may be a polyimide material, such as polyimide resin, or an epoxy. According to one embodiment, the polymer may be photosensitive such that when the material is exposed to light, such as ultraviolet (UV) light, the photosensitive material reacts. In certain instances, the UV light causes crosslinking between polymer chains that results in forming a stable polymeric network, thereby hardening the material. Non-limiting examples of photosensitive materials include photosensitive epoxies, polyimide, and epoxy-based photoresist materials, such as B-stage polymers. Some examples of these materials include SU-8 photoresist (commercially available from MicroChem Corp.), benzocyclobutene (BCB), and mr-I 9000 (commercially available form Micro Resist Technology GmbH). In some embodiments, the structure material 120 may be deposited to a thickness of from about 3 microns to about 5 microns, although other thicknesses are within the scope of this disclosure. As will be understood by those of skill in the art, the thickness of the structure material 120 may depend on the desired application and/or the dimensions of the 3D feature 140. According to embodiments that use photosensitive structure material, light may be used to cause the structure material 120 to at least partially polymerize. For instance, the structure material 120 may be exposed to light, such as UV light, by exposing light from above (i.e., directly onto the upper surface of the structure material 120) or from below (i.e., from underneath the preparation substrate). The structure material 120 may also be “cured” or at least partially polymerized using other techniques, such as heat or other thermal techniques. FIG. 6C illustrates one embodiment of a process 604 for depositing the structure material.

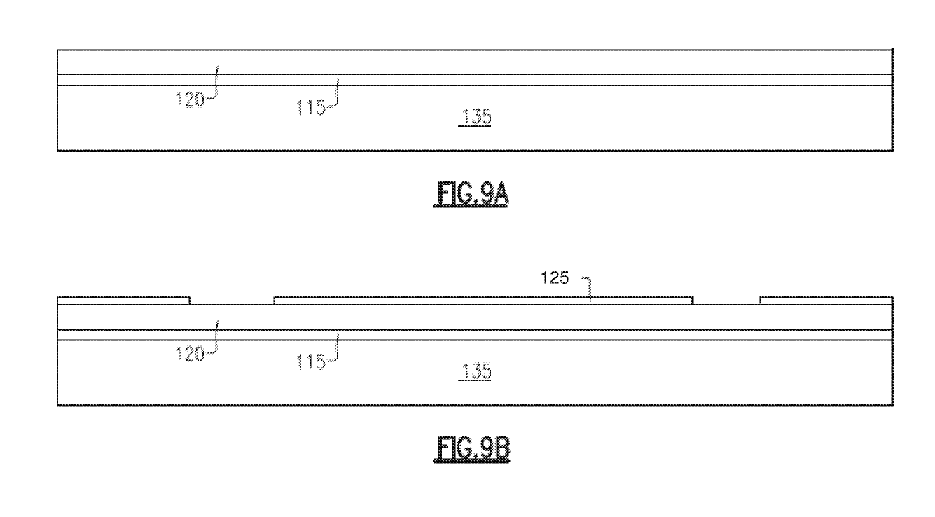

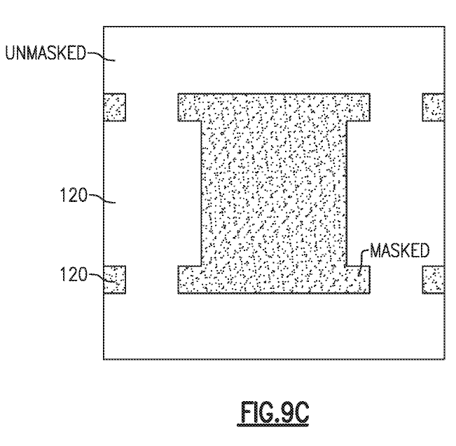

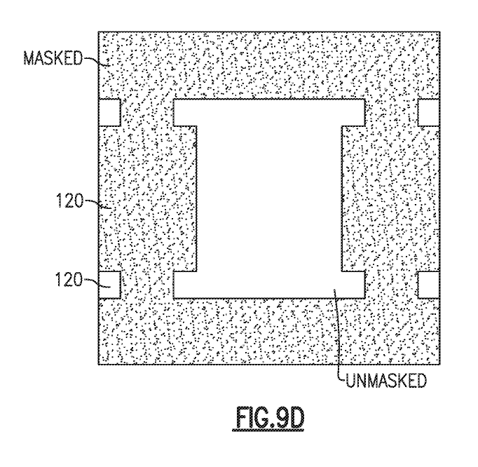

In this example, the preparation substrate is prepared using the process shown in FIGS. 8A and 8B, and therefore features a preparation substrate 135 with a planar upper surface 137 that has been covered with a layer of temporary bonding material 115 (FIG. 8B). A layer of structure material 120 is deposited onto the layer of temporary bonding material 115, as shown in FIG. 9A. At least a portion of the structure material 120 may be masked in step 632, as shown in FIG. 9B. Several different techniques may be used for masking the structure material 120. According to some embodiments, a shadow or stencil mask may be used. For example, a masking material 125 may be deposited or positioned onto the upper surface of the structure material 120, as shown in FIG. 9B. The masking material 125 functions to define unmasked and masked regions of the structure material. The masking material 125 may be a masking material as discussed above in reference to FIGS. 7A-7D. According to another embodiment, masking is performed using a photolithographic method, as described above. In this instance, the photolithographic process includes a photomask that functions as the masking material 125.

According to some embodiments, the masking material 125 functions to protect the masked regions of the structure material when the unmasked region is exposed to light (step 634) and/or to a removal process (step 636). For example, light may be directed onto the masked and unmasked regions of the structure material 120, which functions to at least partially polymerize the structure material in the unmasked regions. A top view of one example of a structure resulting from this process is shown in FIG. 9C. The masked portion in FIG. 9C corresponds to unexposed portions of the structure material that are later removed (step 636), and the unmasked portions correspond to the first portion 142 and the second portion 145 of the structure material 120. The masking material 125 may be configured to define the second portion 145 such that it has a lateral cross-section with at least one of a different dimension and a different shape than a corresponding lateral cross-section of the first portion 142. Once the unmasked portions of the masking material are removed (step 636), a structure material 120 as configured in FIG. 9E results, which includes a first portion 142 and a second portion 145. In this example, the second portion 145 has a horizontally oriented lateral cross-section with a different width than the width of the corresponding lateral cross-section of the first portion 142.

According to other embodiments, the exposure step of 634 is not performed after the masking step 632, and instead a removal process 636, such as an etch process, is conducted after the masking step 632 (see FIG. 6C), which etches away or otherwise removes the unmasked portions of the structure material 120. For instance, an etch process may be performed through openings in the masking material 125, which may be configured as shown in FIG. 9D. Once the masking material 125 is removed, the structure material 120 may be exposed to light to cure or at least partially polymerize the unmasked regions of the structure material 120. This process may also result in the example of the structure material 120 shown in FIG. 9E. In this instance, the masked region corresponds to the first portion 142 and the second portion 145 of the structure material 120.

As shown by the arrows in FIG. 6C, one or more of the masking (632), exposing (634), and removal (636) steps may be repeated to create a structure material having a desired size and/or shape.

FIG. 6D illustrates an example process 606 for preparing a structure material 120 that is photosensitive. According to this example, the structure material 120 includes a first portion 142 having a first material composition and a second portion 145 that has a different material composition. In addition, the second portion 145 may have a lateral cross-section with at least one different dimension and/or shape than a corresponding lateral cross-section of the first portion 142.

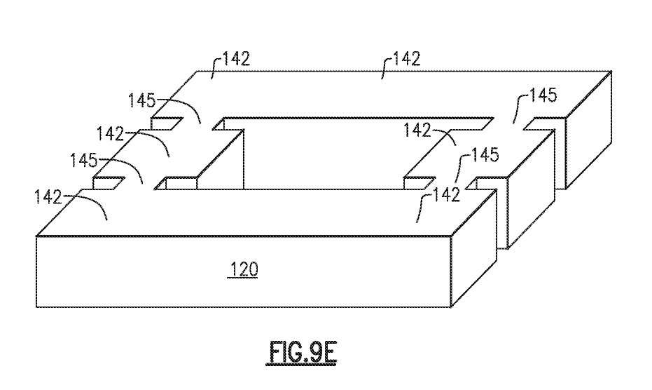

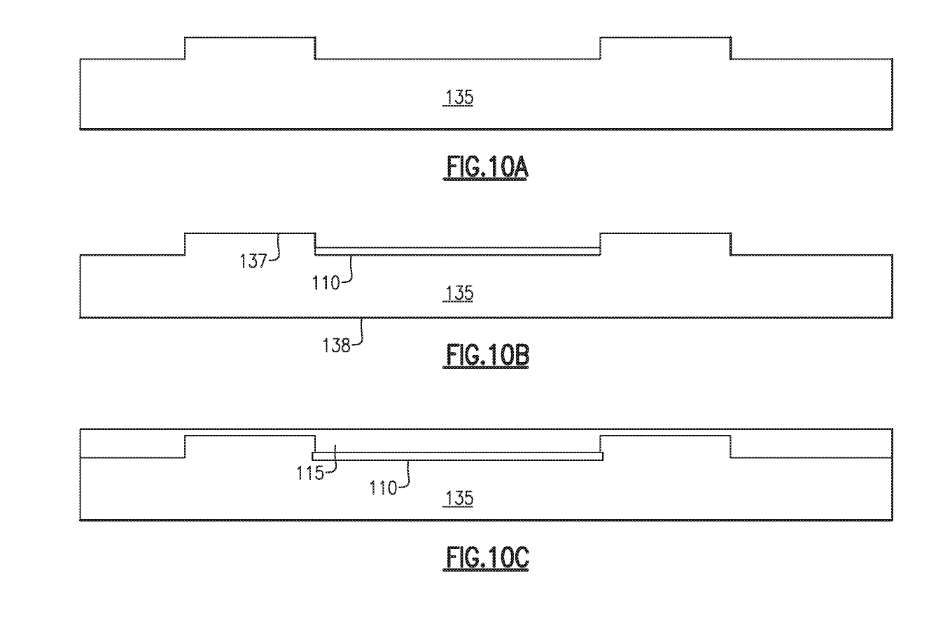

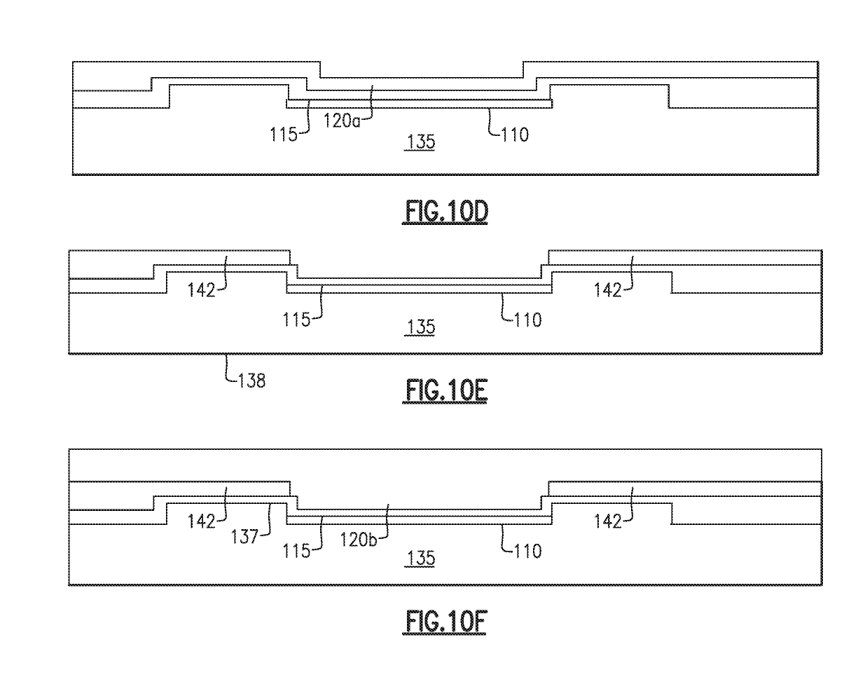

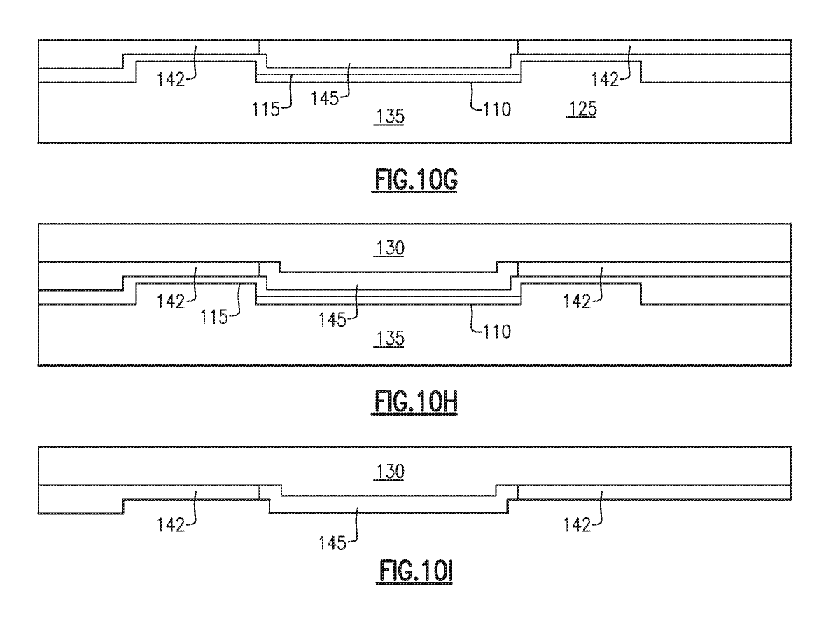

The process begins at step 610 by taking a preparation substrate 135 (see FIG. 10A) that has been prepared according to the process shown in FIGS. 7A-7C and masking at least a portion of its upper or first surface 137 (see FIG. 10B). According to this embodiment, step 610 includes depositing a layer of optical masking material 110 onto at least a portion of the surface of the preparation substrate 135. According to the placement of the optical masking material 110 in FIG. 10B, the optical masking material 110 functions to block light when a light source is applied to a bottom or second surface 138 of the template wafer substrate 135. Non-limiting examples of suitable optical masking materials include chrome or chrome-based materials such as chrome oxide, chrome oxynitride, titanium, tungsten, and the like. Other materials are also within the scope of this disclosure, so long as they are suitable for blocking light of a desired wavelength(s) and they do not otherwise interfere with processing and/or functionality of the methods and systems described herein. The optical masking material 110 may be deposited using any one of a number of different deposition techniques. For example, portions of the first surface 137 of the preparation substrate 135 may be masked off where optical masking material is not desired, and then a layer of optical masking material 110 may be deposited using an evaporation or sputtering process, as understood by those skilled in the art. According to some embodiments, the layer of optical masking material 110 may have a thickness in a range of about 500 Angstroms to about one micron. The thickness of the optical masking material 110 may depend on the type of material used, and is therefore deposited at a thickness so as to provide the light-blocking function.

At step 620, the preparation substrate 135 is treated so that the first surface 137 has or is otherwise characterized by a low bond strength. This is similar to step 620 discussed above with reference to FIG. 6B, but in this instance the layer of temporary bonding material may be deposited on both the first surface 137 of the preparation substrate 135 and the layer of optical masking material 110, as shown in FIG. 10C.

At step 630, a layer of structure material having a first material composition (labeled as “structure material A” in FIG. 6D and as 120a in FIG. 10D) is deposited onto the temporary bonding material 115. According to at least one embodiment, the structure material 120 may be deposited using the aforementioned spin-coat or spray-on techniques.

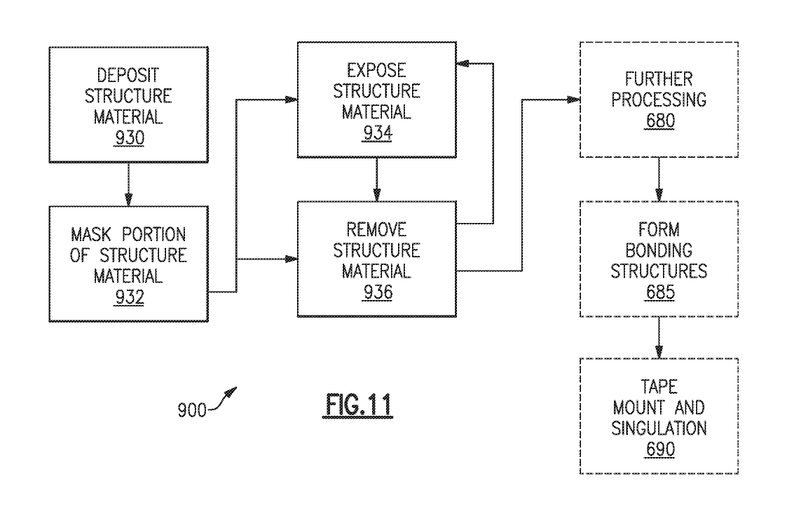

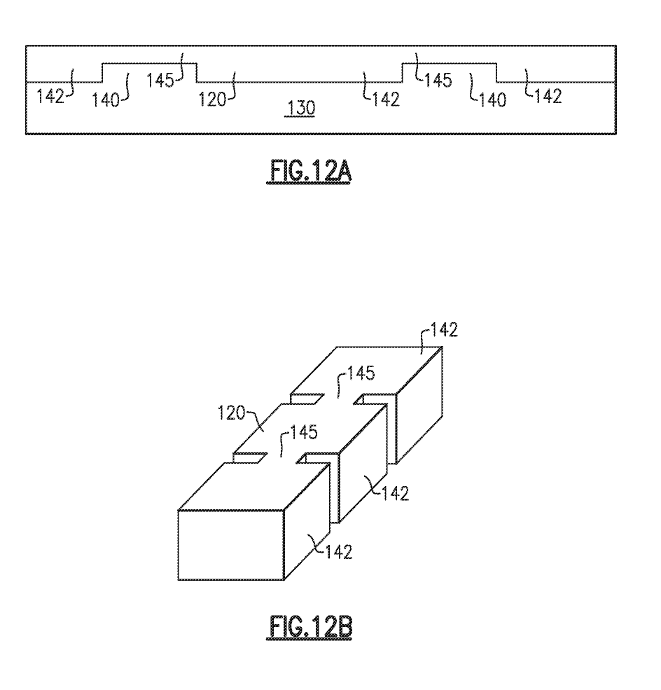

In step 635 and as illustrated in FIG. 10E, the structure material 120a is exposed to light, such as UV light, thereby causing the exposed portions of the structure material 120a to at least partially polymerize. For example, the second surface 138 of the preparation substrate 135 may be flood exposed with UV light. The light is blocked from the portions of the structure material 120 that are positioned “over” the optical masking material 110, since the optical masking material 110 reflects (or absorbs, depending on the material) the light. These blocked portions of the structure material 120 remain unreacted, and may be developed or otherwise removed in step 640 using any one of a number of different removal techniques, such as a wet etch process. As discussed further below in reference to FIG. 11, a photolithographic method may also be used where the upper surface 137 of the preparation substrate 135 is flood exposed with UV light. According to one embodiment, portions of the unreacted structure material 120 may be removed using one or more organic solvents, such as an SU-8 developer material (commercially available from MicroChem Corp.) or propylene glycol methyl ether acetate (PGMEA), such as in instances where SU-8 is used as the structure material 120. In this example, the areas where structure material 120a remains correspond to the first portion 142 of structure material.

In steps 645-655, deposition, exposure, and removal process are performed in a similar manner as in steps 630, 635, and 640, but in this instance the structure material has a different material composition than that of structure material 120a deposited in step 630 and the exposure step performs a different function. At step 645, a layer of structure material having a second material composition (labeled as “structure material B” in FIG. 6D and as 120b in FIG. 10F) that is different than the first material composition of structure material 120a is deposited onto the temporary bonding material 115 (which was exposed after the removal of the first structure material 120a) and the first portion 142 of structure material 120a. For instance, structure material 120b may have physical properties that make it, once cured, more “elastic” or “flexible” than structure material 120a. At step 650 structure material 120b is exposed to light, for example, by flood exposing the first surface 137 of preparation substrate 135 with UV light (i.e., upper surface of structure material 120b), which functions to at least partially polymerize or cure structure material 120b. At step 655, at least a portion of the structure material 120b is removed (FIG. 10G) using a dry or wet etch technique. For instance, structure material 120b may be etched until the upper or outer surface of the first portion 145 of structure material 120a is reached, resulting in a planar surface, as shown in FIG. 10G.

FIG. 10H shows an example of the structure corresponding to step 670 of FIG. 6A, where the receiving substrate 130 may be attached to at least a portion of the structure materials 120a and 120b using similar bonding conditions as discussed in further detail below. In this particular example, the receiving substrate 130 has a step (i.e., a 3D feature) in the vicinity of the second portion 145 of the structure material 120b such that when the structure material is bonded to the receiving substrate 130, the second portion 145 having the different material composition conforms to the edges and contours of the step, thereby avoiding the voids shown in FIG. 1B.

FIG. 10I corresponds to step 675 of FIG. 6A, where the preparation substrate 135 is removed, leaving the first portion 142 and second portion 145 of the structure material attached to the receiving substrate 130. The temporary bonding material 115 may be removed using any one of a number of different removal techniques, such as by exposing the temporary bonding material 115 to a release agent and is discussed in further detail below. For instance, in embodiments where PVA is used as the temporary bonding material 115, the release agent may be water.

The example discussed above in reference to FIGS. 10A-10I may also be performed using a preparation substrate 135 such as that shown in FIG. 8A that includes a planar upper surface instead of the 3D surface of the preparation substrate 135 of FIG. 10A. The resulting difference in these techniques is that the outer surface or profile of the structure material 120 (once attached to the receiving substrate 130) may be planar instead of exhibiting the 3D topography shown in FIG. 10I.

Referring again to method 600 of FIG. 6A, once the structure material 120 has been deposited (step 630), at step 670 the receiving substrate 130 is attached to at least a portion of the structure material 120. For instance, the receiving substrate 130 may be attached to the first portion 142 and the second portion 145 of the structure material 120. In accordance with some embodiments, the receiving substrate 130 has a first surface that includes at least one 3D feature and the receiving substrate 130 is bonded to the structure material 120 in such a way so that the second portion 145 of the structure material is positioned over at least a portion of a 3D feature.

In some embodiments, the receiving substrate 130 is bonded to the layer of structure material 120 at an elevated temperature under pressure for a predetermined length of time. For instance, when SU-8 is used as the structure material 120, the bonding conditions may be at a temperature from about 150° C. to about 300° C. and a pressure of from about 0.5 MPa to about 2 MPa for a time of from about 5 minutes to about 45 minutes. In one embodiment, the structure material 120 is SU-8 that is cured to a B-stage, and the bonding conditions are performed such that they are appropriate for B-stage SU-8. In addition, the bonding process may be performed under vacuum conditions. In certain instances, this may create a cavity 150 that is also under vacuum pressure. According to some embodiments, additional pressure does not need to be applied during the bonding process.

At step 675, the preparation substrate 135 may be removed, thereby leaving the structure material 120 attached to the receiving substrate 130, as illustrated in FIG. 10I. In some instances, removing the preparation substrate 135 includes removing the temporary bonding material 115. The temporary bonding material 115 may be removed using any one of a number of different removal techniques, such as by exposing or otherwise contacting the temporary bonding material 115 with a release agent, such as a solvent and/or through a thermal process, such as by exposing the temporary bonding material 115 to heat. According to some embodiments, a developer material, including developer products sold by MicroChem Corp. (“MCC”), such as MCC 101 may be used as a release agent. According to at least one embodiment, the release agent may be an inorganic solvent, such as water. For example, PVA (when used as a temporary bonding material 115) may be dissolved in water. The release agent may also be one that is recommended by the manufacturer of the temporary bonding material 115. For instance, product information published by the manufacturer of the temporary bonding material 115 may include a list of one or more suitable release agents that may be used for dissolving or otherwise removing the temporary bonding material. According to some embodiments, a “dry” transfer is performed, meaning that the preparation substrate 135 is removed without the use of any liquids, such as liquid bonding materials and/or solvents.

Steps 680, 685, and 690 of FIG. 6A may optionally be performed using the receiving substrate 130 with the attached layer of structure material 120. For example, in step 680 additional processing may be performed, such as by adding other layers of material and/or removing material that provides functionality to the electronic devices or packaging. In step 685, bonding structures that function to provide electrical connectivity to electrical devices disposed on the receiving substrate may be added to the receiving substrate. For instance, according to some embodiments, via openings may be formed through one or more portions of the structure material 120 surrounding a cavity, and the vias may extend to the underlying receiving substrate 130 (or bonding structures formed thereon). These via openings may subsequently be filled with conductive material, such as metal. In certain instances, these bonding structures, such as the conductive vias, form the electrical contact between elements of the package, such as the electrical devices disposed within the cavity, and the outside of the package. According to other embodiments, sealing structures may be added to regions of the receiving substrate 130 that are outside the cavity. These may aid in sealing the packaged device from external environments outside the package. Step 690 includes tape mounting the packaged devices to an adhesive-coated tape, and then performing singulation using a die cutting process.

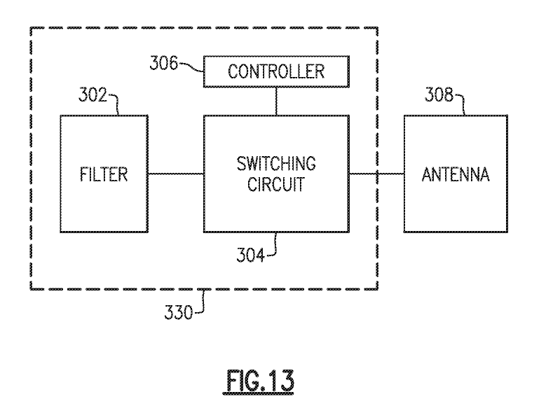

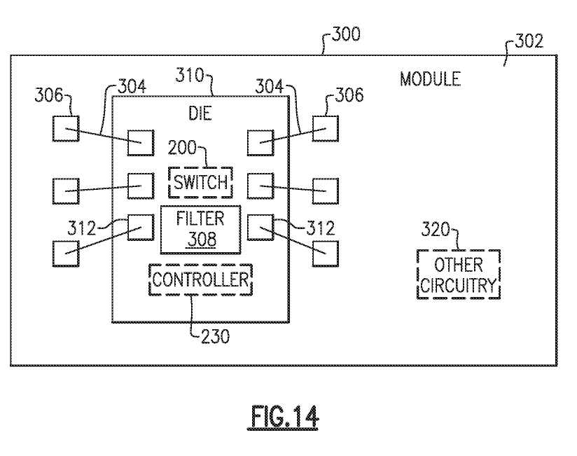

According to some embodiments, the structure material 120 may be formed directly on the receiving substrate 130. For instance, FIG. 11 illustrates a flow diagram of one example of a method 900 of forming a packaged electronic device that includes one or more of the elements discussed above in reference to FIGS. 2, 4, and 5 and includes steps that allow for the structure material 120 to be formed directly on the receiving substrate. At step 930, a layer of structure material 120 is deposited onto the receiving substrate 130 (FIG. 12A). According to the example shown in FIG. 12A, a first surface of the receiving substrate 130 includes at least one 3D feature 140, which in this instance is a step. At step 932, at least a portion of the structure material 120 is masked off. The masking may be performed using any of the techniques described above, including a shadow or stencil mask or photolithographic technique. According to some embodiments, the portion that is not masked may correspond to both the first portion 142 and the second portion 145 of the structure material 120. In a similar manner as discussed above in reference to FIGS. 9A-9E, according to the configuration, either the “open” or the “masked” areas of the mask may correspond to the first portion 142 and the second portion 145 of the structure material. Either way, the mask is configured to define a lateral cross-section of the second portion 145 to have at least one different dimension and/or shape than the corresponding lateral cross-section of the first portion 142. Depending on the configuration, an exposure step 934 or a removal step 936 are performed after the masking step 932. For instance, at step 934 the structure material may be exposed to light, so that the “open” areas of the mask are polymerized, and after the mask is removed, at step 936 the unexposed portions of the structure material are removed. According to another example, the removal step 936 is performed after the masking step 932, such as by etching through the “open” areas of the mask. Once the mask is removed, the structure material may be exposed to light at step 934. One example of at least a portion of structure material 120 resulting from this process is shown in the cross-sectional side view as shown in FIG. 12A (as bonded to the receiving substrate 130), and the perspective view (shown without the receiving substrate 130) shown in FIG. 12B. As illustrated in FIG. 12A, the second portion 145 has a different width dimension than that of first portion 142 and is configured to be positioned over the “step” feature 140 of the receiving substrate 130.

Embodiments of the structure material described herein can be included in an electronic device or component and/or can be integrated into a variety of different modules including, for example, a stand-alone module, a front-end module, a module combining the component with an antenna switching network, an impedance matching module, an antenna tuning module, or the like. FIG. 13 is a block diagram of a device 330, such as a wireless device, that can be fabricated according to one or more of the processes described herein. Such a device 330 can include one or more acoustic wave filters 302, such as SAW or BAW filters or other similar acoustic wave components, and can be packaged according to one or more of the embodiments as described herein. The device 330 can also include a switching circuit 304. In some embodiments, control of the switching circuit 304 can be performed or facilitated by a controller 306. The device 330 can also be configured to be in communication with an antenna 308.

Embodiments of the structure material disclosed herein, optionally packaged into the device 330 or the module 300 discussed below, may be advantageously used in a variety of electronic devices. Non-limiting examples of the electronic devices can include consumer electronic products, parts of the consumer electronic products, electronic test equipment, cellular communications infrastructure such as a base station, etc. Examples of the electronic devices can include, but are not limited to, a mobile phone such as a smart phone, a telephone, a television, a computer monitor, a computer, a modem, a hand held computer, a laptop computer, a tablet computer, an electronic book reader, a wearable computer such as a smart watch, a personal digital assistant (PDA), a microwave, a refrigerator, an automobile, a stereo system, a DVD player, a CD player, a digital music player such as an MP3 player, a radio, a camcorder, a camera, a digital camera, a portable memory chip, a health care monitoring device, a vehicular electronics system such as an automotive electronics system or an avionics electronic system, a washer, a dryer, a washer/dryer, a peripheral device, a wrist watch, a clock, etc. Further, the electronic devices can include unfinished products.

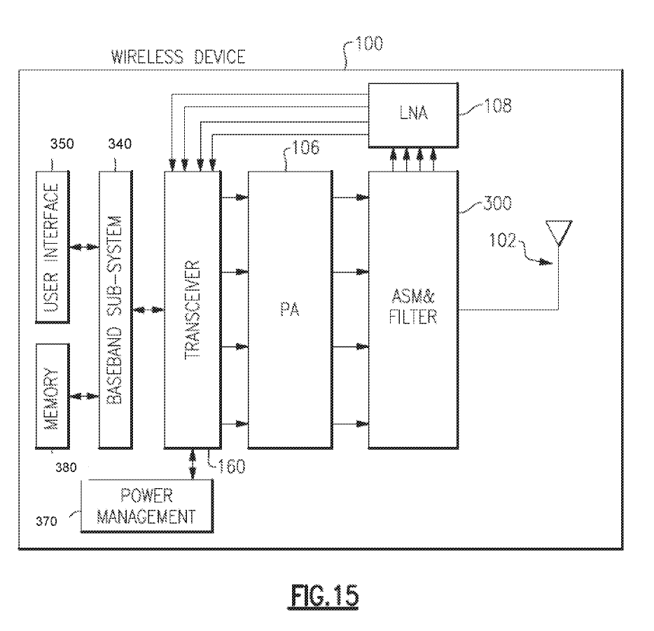

As discussed above, the structure material described herein may be used to package electronic devices such as a mobile communications device or other electronic device. FIG. 14 is a block diagram of one example of a module 300, such as an antenna switch module, that can include an embodiment of the structure material described herein. The module 300 includes a packaging substrate 302 that is configured to receive a plurality of components. In some embodiments, such components can include a die 310 that is packaged according to one or more features as described herein. For example, the die 310 can be formed from a receiving substrate 130 as described above and may be packaged using structure material having portions with different cross-sections, as described herein. The die may also include an acoustic wave filter 308, such as a SAW or BAW filter or other similar acoustic wave component, a switch 200, such as an antenna switch, and optionally other circuitry or components, such as a controller 230, for example. A plurality of connection pads 312 can facilitate electrical connections such as wirebonds 304 to connection pads 306 on the substrate 302 to facilitate passing of various power and signals to and from the die 310. In some embodiments, other circuitry or components 320 can be mounted on or formed on the packaging substrate 302. For example, the components 320 may include phase shifters, filter circuitry, modulators, demodulators, down converters, and the like, as would be known to one of skill in the art of semiconductor fabrication in view of the disclosure herein. In some embodiments, the packaging substrate 302 can include a laminate substrate.

In some embodiments, the module 300 can also be packaged using the structure material as described herein. For example, the structure material may be prepared according to the methods disclosed herein to form one or more packaging structures with improved coverage over 3D features, such as steps and recesses. The resulting packaging structures may, for example, provide protection and facilitate easier handling of the module 300. In certain instances, the packaging structure may include an overmold formed over the packaging substrate 302 that is dimensioned to substantially encapsulate the various circuits and components thereon. It will be understood that although the module 300 is described in the context of wirebond-based electrical connections, one or more features of the present disclosure can also be implemented in other packaging configurations, including flip-chip configurations.

In some implementations, a device packaged according to one or more of the embodiments described herein can be included in an RF device such as a wireless device. The packaging structures described herein can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, a wireless router, a wireless access point, a wireless base station, modem, communication network, or any other portable or non-portable device configured for voice and/or data communication.

FIG. 15 is a block diagram of a wireless device 100 that, according to certain embodiments, may implement the structure material disclosed herein. The wireless device 100 can be a cellular phone, smart phone, tablet, modem, or any other portable or non-portable device configured for voice or data communications. The wireless device 100 includes an antenna 102 and can transmit and receive signals from the antenna 102.

The wireless device 100 further includes a transceiver 160. The transceiver 160 is configured to generate signals for transmission and/or to process received signals. Signals generated for transmission are received by the power amplifier (PA) 106, which amplifies the generated signals from the transceiver 160. Received signals are amplified by the low noise amplifier (LNA) 108 and then provided to the transceiver 160. The antenna switch module and filter component 300 can be configured to perform one or more functions. For instance, the antenna switch module portion of the component 300 can switch between different bands and/or modes, transmit and receive modes, etc. The acoustic wave filter of component 300 may be used to perform a filtering function of the signal so as to allow through desired channels(s). As is also shown in FIG. 15, the antenna 102 both receives signals that are provided to the transceiver 160 via the antenna switch module and filter component 300 and the LNA 108 and also transmits signals from the wireless device 100 via the transceiver 160, the PA 106, and the antenna switch module and filter component 300. However, in other examples multiple antennas can be used. Although not shown in FIG. 15, the antenna switch module and filter component 300 may be implemented as separate components.

The power amplifier 106 can be used to amplify a wide variety of RF or other frequency-band transmission signals. For example, the power amplifier 106 can receive an enable signal that can be used to pulse the output of the power amplifier to aid in transmitting a wireless local area network (WLAN) signal or any other suitable pulsed signal. The power amplifier 106 can be configured to amplify any of a variety of types of signal, including, for example, a Global System for Mobile (GSM) signal, a code division multiple access (CDMA) signal, a W-CDMA signal, a Long Term Evolution (LTE) signal, or an EDGE signal. In certain embodiments, the power amplifier 106 and associated components including switches and the like can be fabricated on GaAs substrates using, for example, pHEMT or BiFET transistors, or on a Silicon substrate using CMOS transistors.

The wireless device 100 further includes a power management system 370 that is connected to the transceiver 160 that manages the power for the operation of the wireless device 100. The power management system 370 can also control the operation of the baseband processing circuitry 340 and other components of the wireless device 100. The power management system provides power to the various components of the wireless device 100. Accordingly, in certain examples the power management system 370 may include a battery. Alternatively, the power management system 370 may be coupled to a battery (not shown in FIG. 15).

The baseband processing circuitry 340 is shown to be connected to a user interface 350 to facilitate various input and output of voice and/or data provided to and received from a user. The baseband processing circuitry 340 can also be connected to a memory 380 that is configured to store data and/or instructions to facilitate the operation of the wireless device, and/or to provide storage of information for the user.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while acts of the disclosed processes are presented in a given order, alternative embodiments may perform routines having acts performed in a different order, and some processes or acts may be deleted, moved, added, subdivided, combined, and/or modified. Each of these processes or acts may be implemented in a variety of different ways. Also, while processes or acts are at times shown as being performed in series, these processes or acts may instead be performed in parallel, or may be performed at different times.

The teachings of the invention provided herein can be applied to other systems, not necessarily the system described above. The elements and acts of the various embodiments described above can be combined to provide further embodiments.

Having thus described several aspects of at least one embodiment of this invention, it is to be appreciated various alterations, modifications, and improvements will readily occur to those skilled in the art. Any feature described in any embodiment may be included in or substituted for any feature of any other embodiment. Such alterations, modifications, and improvements are intended to be part of this disclosure, and are intended to be within the scope of the invention. Accordingly, the foregoing description and drawings are by way of example only.

What is claimed is:

1. A bonding structure for packaging an electronic device comprising:
a receiving substrate having a first surface including at least one three-dimensional structure; and
a layer of structure material disposed on the first surface and including a first portion and a second portion, the second portion at least partially covering the at least one three-dimensional structure, the first portion having a first lateral cross-section and the second portion having a second lateral cross-section in which at least one of a dimension and a shape of the layer of structure material is different than in the first lateral cross-section.

2. The bonding structure of claim 1 wherein the first and the second lateral cross-sections are vertically oriented.

3. The bonding structure of claim 2 wherein the second lateral cross-section has at least one of a different width dimension and a different height dimension than the first lateral cross-section.

4. The bonding structure of claim 2 wherein the second lateral cross-section has a different shape than the first lateral cross-section.

5. The bonding structure of claim 1 wherein the first and the second lateral cross-sections are horizontally oriented.

6. The bonding structure of claim 5 wherein the second lateral cross-section has a different shape than the first lateral cross-section.

7. The bonding structure of claim 6 wherein the first lateral cross-section has a rectilinear shape and the second lateral cross-section has a curvilinear shape.

8. The bonding structure of claim 6 wherein the first lateral cross-section has a rectangular or square shape and the second lateral cross-section has at least one tapered edge.

9. The bonding structure of claim 7 wherein the second lateral cross-section includes a hollow region.

10. The bonding structure of claim 1 wherein the second portion has a different material composition than the first portion.

11. A transferable structure, comprising
at least one layer of structure material having a first portion and a second portion, the first portion having a first lateral cross-section and the second portion having a second lateral cross-section in which at least one of a dimension and a shape of the layer of structure material is different than in the first lateral cross-section.

12. The transferable structure of claim 11 wherein the first and the second lateral cross-sections are vertically oriented.

13. The transferable structure of claim 12 wherein the second lateral cross-section has a different dimension than the first lateral cross-section and the different dimension includes at least one of a width and a height of the second lateral cross-section.

14. The transferable structure of claim 12 wherein the first and the second lateral cross-sections are horizontally oriented.

15. The transferable structure of claim 14 wherein the second lateral cross-section has a shape with at least one tapered edge.

16. The transferable structure of claim 14 wherein the second lateral cross-section has a curvilinear shape.

17. The transferable structure of claim 14 wherein the second lateral cross-section has a different width dimension than the first lateral cross-section.

18. The transferable structure of claim 14 wherein the second lateral cross-section has a rectilinear shape.

19. The transferable structure of claim 14 wherein the second lateral cross-section includes a hollow region.

20. The transferable structure of claim 11 wherein the at least one layer of structure material is a photosensitive polymer.

21. The transferable structure of claim 11 disposed in a packaged module.

22. The transferable structure of claim 21 wherein the packaged module is an electronic device module that includes an acoustic wave filter.

23. A method of forming a bonding structure for a packaged electronic device, comprising:
depositing a layer of structure material onto at least a portion of a surface of a first substrate;
masking the layer of structure material to define a masked region and an unmasked region of the structure material, the unmasked region of the structure material defined by a first portion with a first cross-section and a second portion with a second cross-section, the first cross-section and the second cross-section oriented horizontally and at least one of a dimension and a shape of the second cross-section is different than a dimension and shape of the first cross-section;
exposing the masked and unmasked regions of the structure material to a source of light to at least partially cure the unmasked region; and
removing the masked region of the structure material.

24. The method of claim 23 wherein the surface of the first substrate is defined by at least one three-dimensional structure and masking comprises aligning the second portion of the unmasked region to be positioned over at least a portion of the three-dimensional structure.

25. The method of claim 23 further comprising depositing a layer of temporary bonding material onto the surface of the first substrate prior to depositing the layer of structure material.

26. The method of claim 25 further comprising bonding the unmasked region of the structure material to a surface of a second substrate.

27. The method of claim 26 wherein the surface of the second substrate is defined by at least one three-dimensional structure and bonding comprises positioning the second portion to be disposed over at least a portion of the three-dimensional structure.
